(19) United States
(12) Patent Application Publication
(10) Pub. No.: US 2016/0293541 A1
(43) Pub. Date: Oct. 6, 2016

(54) STRUCTURED INTEGRATED CIRCUIT DEVICE WITH MULTIPLE CONFIGURABLE VIA LAYERS

(71) Applicant: eASIC Corporation, Santa Clara, CA (US)

(72) Inventors: Alexander ANDREEV, San Jose, CA (US); Ranko SCEPANOVIC, Saratoga, CA (US)

(21) Appl. No.: 14/676,497

(22) Filed: Apr. 1, 2015

(51) Int. Cl. H01L 23/522; H01L 21/768; H01L 21/8234; H01L 27/118

(52) U.S. Cl. CPC H01L 23/5226; H01L 27/11807; H01L 21/76877; H01L 21/823475; H01L 2027/11888

(57) ABSTRACT

An integrated circuit may include a multi-layer structure having alternating metal interconnection layers and via layers superimposed on a base layer having electronic components, functional blocks, or both. At least two of the via layers may be customizable and may be used to form customized interconnections that may customize functionality of the resulting integrated circuit. In a variant, at least some of the layers may have a default structure that may result in a default integrated circuit functionality; the default structure may be changed to customize functionality. One or more metal interconnection layers may also be customizable. Additionally, transistors of the base layer may be customized for speed and/or power consumption by adjusting voltage thresholds and/or gate lengths.

### FIELD OF THE DISCLOSURE

Aspects of the present disclosure may relate to the design and fabrication of structured integrated circuits (ICs) that may also have a high degree of configurability. Various aspects may related to structured application-specific ICs (ASICs).

### BACKGROUND

A structured ASIC, or IC in general, may have a combination of pre-made elements that may be manufactured in an initial manufacturing process and kept in inventory. The elements may later be interconnected to form a circuit or may be customized by means, e.g., of masks. In one or more further manufacturing processes. Such interconnections and customizations may result in greater flexibility in that the resulting IC may be customized for a particular customer application or to have particular characteristics, such as high speed, low power, etc. The result of such an approach to IC production may be an ability to amortize non-recurring engineering (NRE) costs over a wide range of devices and/or multiple customer applications. This approach may also result in improved yields and/or reduced manufacturing time, from tape-out to packaged chip.

While there may exist some methods for designing and manufacturing structured, configurable ICs, it may desirable, to improve upon existing techniques, in order to obtain even greater flexibility and/or to further improve characteristics of the resulting ICs for the purposes to which they are tailored.

### SUMMARY OF THE DISCLOSURE

Various aspects of the disclosure may be directed to techniques that may be used to increase flexibility and/or efficiency of customizable IC design. Such techniques may include, for example, but are not limited to, the use of multiple customizable via layers and/or customization of voltage thresholds in devices and/or customization of one or more metal layers. Such latter customization may include removal of unused metal and/or rerouting of metal within one or more metal layers.

### BRIEF DESCRIPTION OF ACCOMPANYING DRAWINGS

Various aspects of this disclosure will now be discussed in further detail in conjunction with the attached drawings, in which:

FIG. 1 shows an example of a device including multiple metal and via layers, according to various aspects of the disclosure;

FIG. 2 shows a further example of a device including multiple metal and customizable via layers, according to various aspects of the disclosure;

FIG. 3 shows an example of an integrated circuit that may be designed using the example structure of FIG. 2, according to an aspect of the disclosure;

FIG. 4 shows a further example of portion of an integrated circuit that may be designed using the example structure of FIG. 2, according to an aspect of the disclosure;

FIG. 5 shows an example of a logic array structure according to an aspect of the disclosure;

FIGS. 6A and 6B show a schematic and M2/M3 layout of an example of a logic cell, according to an aspect of the disclosure;

FIG. 7 shows an example of a V4-programmable M4/M5 routing fabric, according to an aspect of this disclosure; and

FIG. 8 shows an example of a further customization, according to a further aspect of this disclosure.

### DETAILED DESCRIPTION OF ASPECTS OF THE DISCLOSURE

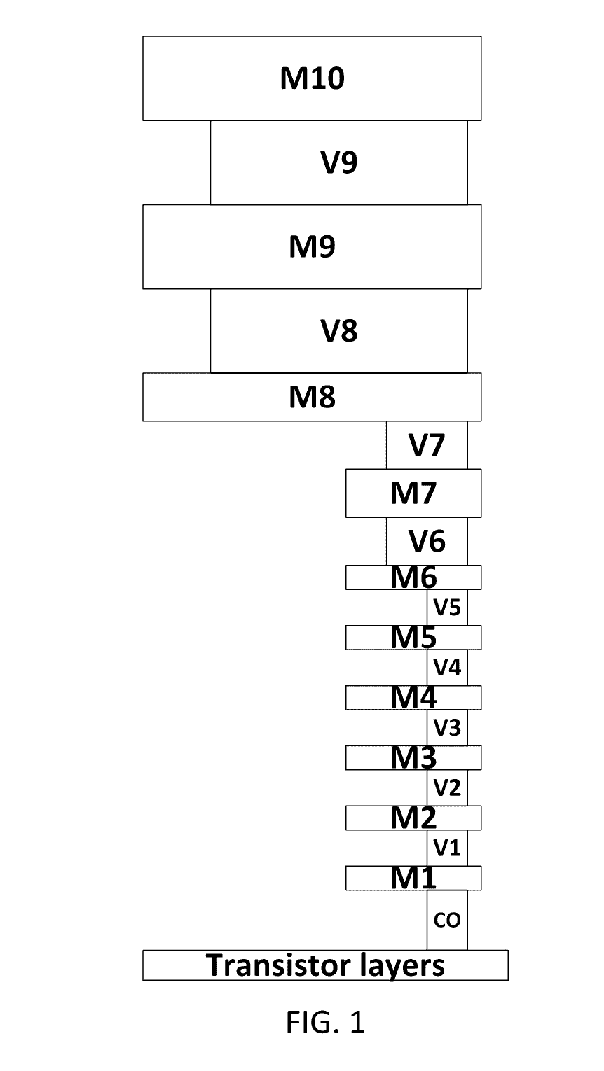

A structured IC may have the form of a series of superimposed layers, a non-limiting example of which is shown in FIG. 1. In the example of FIG. 1, the lowest layer is labeled, “Transistor layers.” This layer may not only contain transistors, per se, but may also include other electronic components, such as, but not limited to, resistors, capacitors, inductors, diodes, et al. Furthermore, the components of the transistor layers may be designed to form various types of functional blocks and sub-blocks, which may include non-programmable and/or programmable blocks. For example, in addition, or alternatively, to individual basic components, such as transistors, various components may be organized into functional blocks/sub-blocks, such as memory, logic devices, buffers, amplifiers, look-up tables, processor units (e.g., but not limited to, arithmetic logic units (ALUs)), high-speed serializers/deserializers (SERDES), etc. (i.e., the complexity of the components of the “transistor layers” may range from very simple to highly complex, as determined by the designer). Some components of the transistor layers may include highly-specialized devices, as well, rather than only generic components. Hence, while referred to herein as “transistor layers,” this may also be referred to by other terms, such as “component layer(s),” “IP core,” et al. Additionally, although labeled “transistor layers,” this may comprise one or more structural layers (e.g., but not limited to, variously-doped different layers of silicon or other semiconductor materials, insulating materials, etc.). Furthermore, components of the transistor layers may be further customizable, for example, various components of the transistor layers may be interconnected to form functional blocks and/or blocks that may be useful for further interconnection into further functional blocks by interconnection layers of various types that may be superimposed on the transistor layers.

For the sake of clarity, it is noted that “functional block” (or “sub-block”) refers to more than just a basic electronic component, such as a transistor, resistor, capacitor, inductor, diode, etc. That is, a “functional block” is used herein to refer to a structure configured to perform some function, such as, but not limited to, data storage and/or retrieval and/or selection (e.g., memory cells, memory blocks, flip-flops, registers, multiplexers, look-up tables, etc.), amplification (e.g., operational amplifiers, etc.), computation (e.g., adders, multipliers, ALUs, etc.), logic operations (e.g., logic gates, comparators, inverters, etc.), data formatting (e.g., a SERDES), and the like, which may be more than can be achieved by a basic electronic component without any specific configuration and/or interconnection with other components (or functional blocks). A functional block may be composed of multiple interconnected electronic components or may be as small as a transistor specifically configured as a transistor amplifier, for example (but not an unconfigured transistor or individual capacitor, resistor, etc.). As noted above, such functional blocks may be interconnected with each other and/or with other electronic components (e.g., transistors and the like) to form further functional blocks, which may generally have even more sophisticated functionalities.

A contact layer CO may be superimposed directly on the transistor layers. Contact layer CO may include metal or other conductive substances. The contact layer CO may provide contact points, which may include contact points to at least one further superimposed layer (e.g., one or more metal interconnection layers) for further interconnection/connectivity. The transistor layers or the combination of the transistor layers with the contact layer CO may be a standard device that may be manufactured in large quantities, if desired, to provide an inventory that may be used to create further-customized devices. It is noted that, according to some aspects of the disclosure, the contact layer CO may be customizable.

Above the contact layer CO, there may be superimposed a series of alternating metallization and via layers. In the example of FIG. 1, layers M1-M10 are metal layers, and layers V1-V9 are via layers. While ten metal and nine via layers are shown, the invention is not thus limited, and the numbers of such layers may be arbitrary. The metal layers may provide horizontal connectivity among or between components of lower layers, while the via layers may provide vertical connectivity between or among interconnections of various metal layers, where “horizontal” and “vertical” are being used in the sense of the orientation and structures shown in FIG. 1. Note that within a “horizontal” metal layer, it is also common usage to refer to metal strips directed in one direction as “horizontal” and metal strips directed in a perpendicular direction as “vertical.” Unless otherwise specified in this disclosure, “horizontal” and “vertical” are being used in the first sense, i.e., the orientation of the overall structure of a device, rather than in the second sense, i.e., the orientation of structures within a layer of such a structure.

For example, M1 may contain a pattern of metal strips that may interconnect various devices/blocks formed by the transistor layers, and which may be connected to the transistor layers by contact layer CO. M2 may contain another pattern of metal strips for interconnection, for which V1 may determine which interconnected components formed by M1 may be further interconnected by M2 layer. In the example of FIG. 1, this pattern of horizontal (Mn, where “Mn” represents the n^{th} metal layer) connectivity and vertical (Vm, where “Vm” represents the m^{th} via layer) connectivity may continue throughout the device, up to layer M10. These metal and via layers may enable the connection of the various components in/formed by the transistor layers and CO layer to form highly-complex and/or highly-customized devices.

A method of fabricating an integrated circuit may involve forming the transistor layers, forming the contact layer CO, and superimposing the metal and via layers. Customization, as will be further described below, may be performed during the forming of the superimposed metal and via layers.

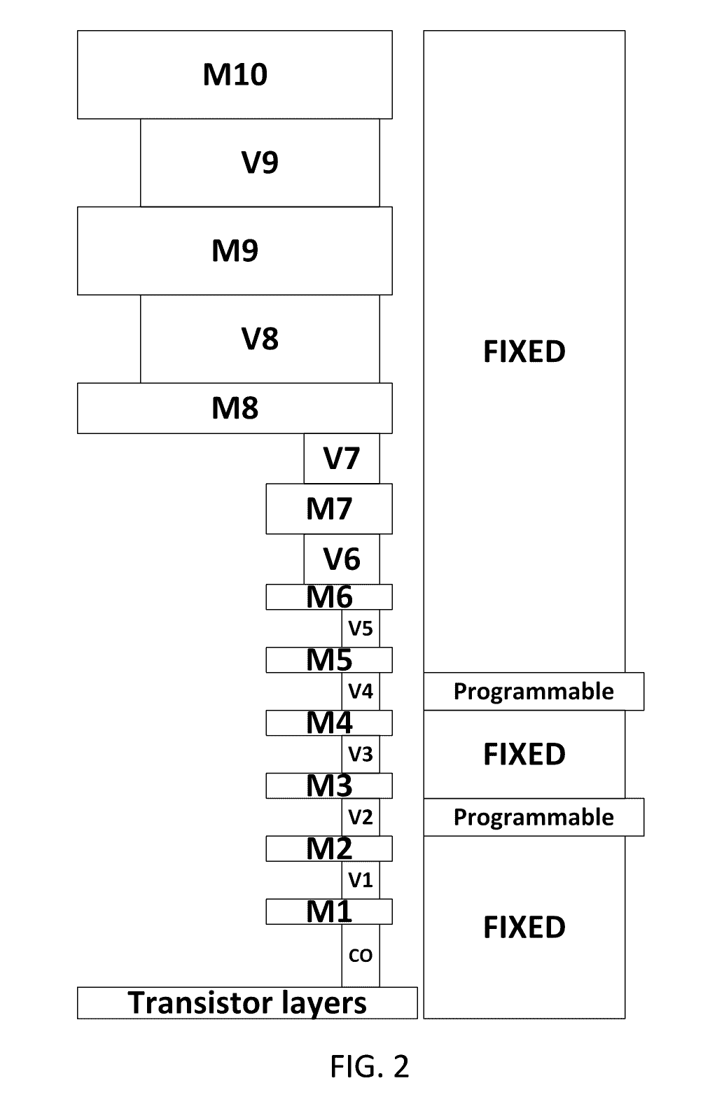

Note that even though the descriptions provided herein may be with respect to the structure as shown, e.g., in FIGS. 1 and 2, and the terms “vertical,” “horizontal,” “upper” and “lower” are used with respect to the orientations shown in these drawings, the invention is not limited to this orientation. Any physical orientation of such a structure is contemplated, and the orientation is not limited to what is shown in FIGS. 1 and 2. For example, the transistor layers may be located on the top, with the metal and via layers progressing downward, a “sideways” implementation may be used, etc.

While the metal layers and via layers may be fixed, to form a standard ASIC, recent technologies may permit the use of customizable via layers that may enable the construction of custom ICs from a “standard” or “common” base device layer (i.e., the transistor layers and connection layer) by customizing the interconnections. For example, eASIC® Corporation has developed such technologies that may use patterned metal layers and/or a customizable via layer to obtain multiple ICs from a standard device layer. See, e.g., U.S. Pat. Nos. 6,331,733, 6,331,790, 6,476,493, 6,642,744, 6,756,811, 6,953,956, 7,098,691, 7,157,937, 7,463,062, 7,514,959, and 7,550,996, which are incorporated by reference herein. However, the techniques disclosed in such patents may generally permit a single customizable via layer; also, such a single via layer may be customized without resorting to mask-based optical lithography and, instead, may be customized using a maskless e-beam process, e.g., as described in U.S. Pat. No. 6,953,956.

Note that a customizable via layer is customizable in the sense that some subset (which may be any subset, including none) of a set of possible vias that may be formed by the customizable via layer may be chosen, e.g., according to some specification, prior to device fabrication, to provide customizability of interconnections. Once the device is fabricated, the resulting vias form non-changeable vertical connectivity. Similarly, a customizable metal layer is customizable in the sense that it may be designed, e.g., according to some specification, to provide custom connectivity paths and the like prior to device fabrication, and once the device is fabricated, the customizable metal layer provides non-changeable horizontal connectivity in that layer. That is, customizable via layers and metal layers may provide flexibility of design of a device prior to fabrication and may allow a single generic structure to be used to create many different specific devices.

The above techniques may be generalized by permitting any or all of via layers V1-V9, using the example of FIG. 1 (to which the invention is not limited; there may be more or fewer metal layers and/or via layers than as shown), to be customizable, which may thus permit greater flexibility of customization. Additionally, any or all of metal layers M1-M10 may be customized, which may provide even further design flexibility.

In a particular variation, a structured, flexible ASIC (SFASIC) may be provided in which each of the layers of the layout shown in FIG. 1 has a default state, and the resulting chip may have a default functionality defined by the default state of all of the layers; however, this is not necessarily the case. However, a manufacturer may benefit from having a default state/functionality that may correspond to a device that may be frequently sold, which may eliminate the need for specific customization when such a device is to be produced, which may, in turn, reduce the cost of manufacturing the device. The SFASIC may be customized, and in particular, one or more particular layers may be changed from their default states to custom states. A hardware design language, such as, but not limited to, register transfer language (RTL), may be used to specify the changes; this may be provided by a particular customer. In some aspects of this, only an arbitrary subset of layout layers may be changed from their default states to custom states. This may involve, for example, translation of the RTL or other language into specific via layer or other layer configurations.

FIG. 2 shows an example in which two of the via layers, V2 and V4, are shown as being customizable; however, the invention is not thus limited, and any subset of via layers (and/or metal layers) may be chosen for customization. This specific example of FIG. 2 may enable customizable vertical interconnectivity between M2 and M3 and between M4 and M5. As shown in this example, to which the invention is not limited, the remaining metal and via layers may be fixed.

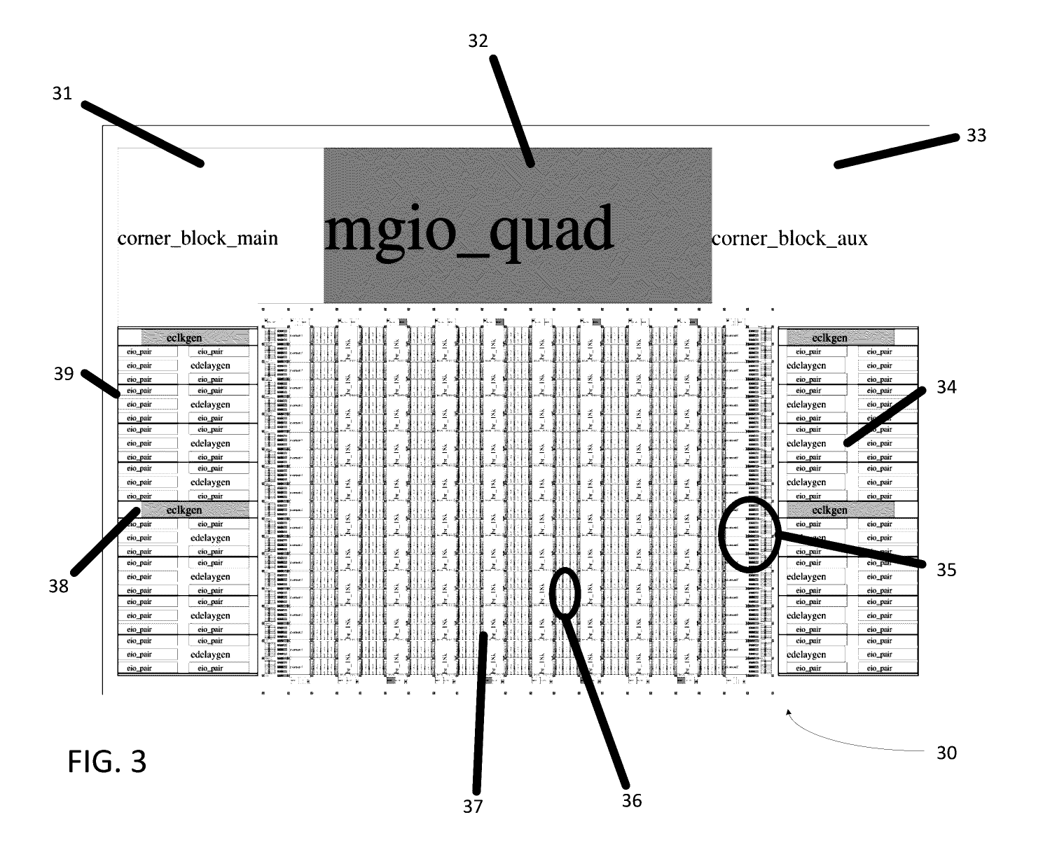

FIG. 3 shows an example of an IC 30 that may be designed using the generic structure example of FIG. 2. FIG. 3 shows a number of different functional blocks of the IC 30. IC 30 may, for example, contain a design-for-test (DFT) microcontroller 31, which may be used to manage memory built-in self-test (BIST) functionality, repair and initialization. This block may be created by means of V2-programmable cells and V2/V4-programmable routing fabric, and its functionality may thus be changed based on customer needs. The V2-programmable cells may be logic cells, which may be used to implement different logic functionality, depending upon how they are programmed. These cells may originally be part of a logic fabric, like logic fabric 36, which may contain such V2-programmable cells that may be interconnected using a V2 and/or V4-programmable routing. The IC may further contain a serializer/deserializer (SERDES) 32, which may be configured for multi-gigabit input/output (MGIO). Static data storage 33 may also be furnished on the IC 30; static data storage 33 may be created using V2-programmable read-only memory (ROM) and/or one-time programmable (OTP) memory, which may be programmable by microcontroller 31. Interconnections may permit the content to be accessed by microcontroller 31 and to be loaded into core memory of the IC 30. One or more delay generators 34 may also be provided; such delay generators 34 may be based on double data rate delay-lock loop (DDRDLL) technology and may, e.g., support strobe shifting for DDR-like interfaces. V4 programmability may be used to create a power-down option for delay generators 34. High-speed logic fabric 35 may be provided, which may support high-speed interfaces; this may be created using V2/V4 programming. The IC 30 of FIG. 3 may also have a memory block 37 that may contain random-access memory (RAM) and/or other memory and/or registers, which may be core memory for the device; V2 may be used to customize user interface variations, such as numbers of words and/or bits and/or double-pumping, which V4 may be used to create a power-down option. One or more clock generators 38 may be provided, which may used phase-locked loop (PLL) technology, and which may combine V2/V4 and/or Joint Test Action Group (JTAG) programmability for changing user clock parameters. Finally, the IC 30 may include V2/V4-programmable input/output (I/O) blocks 39. Such I/O blocks 39 may be programmed by vias to provide, e.g., single differential I/O, pairs of single-ended I/Os, or both. V2/V4-programmability may be used to support different standards and/or voltages.

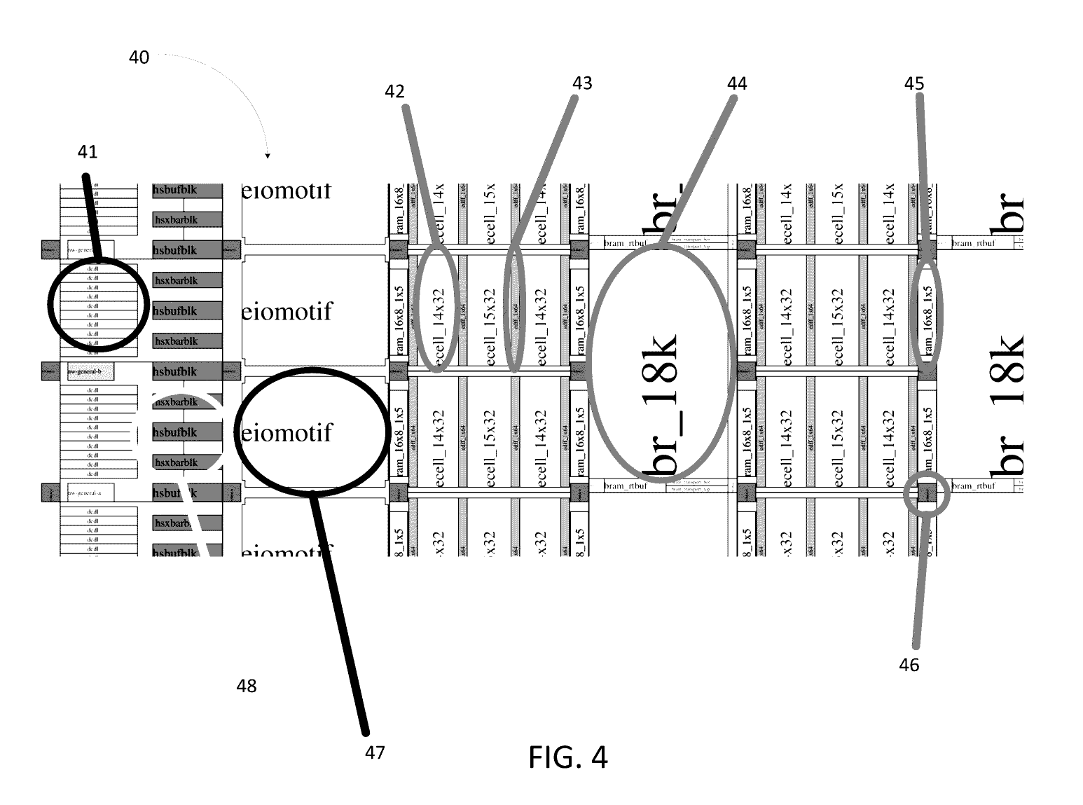

FIG. 4 shows a further example of a portion of a core structure 40 that may be created using V2/V4-programmability, according to an aspect of this disclosure. The structure 40 may include a digitally-controlled delay line (DCDL) 41, which may be used, e.g., for support of high-speed interfaces. V4-programmability may be used to create a power-down option for DCDL 41. The structure 40 may include one or more cells (e.g., eCell™ logic cells by eASIC® Corporation), which may form a cell matrix 42, D-flip flops (DFFs) (e.g., eDFF™ DFFs by eASIC® Corporation), which may form a DFF column 43, block RAM 44, register files 45, etc. The structure 40 may further include one or more clock distribution cells 46, which may be V2-programmable and may utilize a V2/V4 programmable routing fabric that may implement cells and/or high-level layer clock track connections. The structure may further incorporate a high-speed logic fabric 47 (e.g., the eiomotif™ by eASIC® Corporation). This may be a block of V2-programmable cells, which are sequential and/or combinatorial, that may be optimized for high-speed operation, and this may include a V2/V4-programmable routing fabric. Finally, the structure 40 may include a high-speed balancing fabric 48, which may be V2/V4-programmable and may enable one to create highly balanced connections between I/O and core logic.

In a generalization, demonstrated by, but not limited to the above examples, different functional blocks may be obtained by means of the same or different customized layers, even in the same IC. In the examples described above, some functional blocks involve customization of V2, only, some involve customization of V4, only, and some involve customization of both V2 and V4. Additionally, portions of the same functional block may involve customization of different layers or sets of layers (including the possibility that some portion of a given functional block may use no customized layers). In general, a single IC may include multiple functional blocks, and each of the multiple functional blocks may obtained or programmed using different combinations of customized via layers or customized metal layers or both customized via layers and customized metal layers.

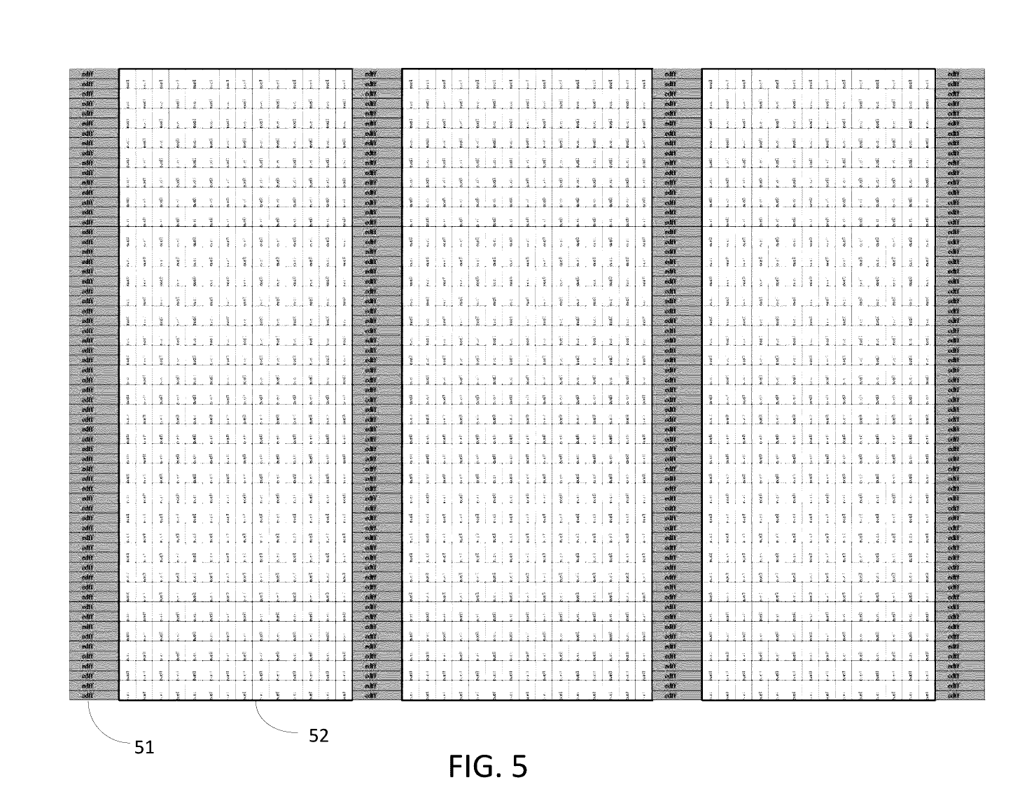

FIG. 5 shows an example of a logic array structure that may, for example, be incorporated into a structure such as structure 40 of FIG. 4. In FIG. 5, logic cells (e.g., eCell™ logic cells) 51 may form a chess board-like pattern, which may be based on variation of V2/V4-based routing between neighboring cells. DFFs (e.g., eDFF™ DFFs) 52 may, e.g., simply be arranged in columns.

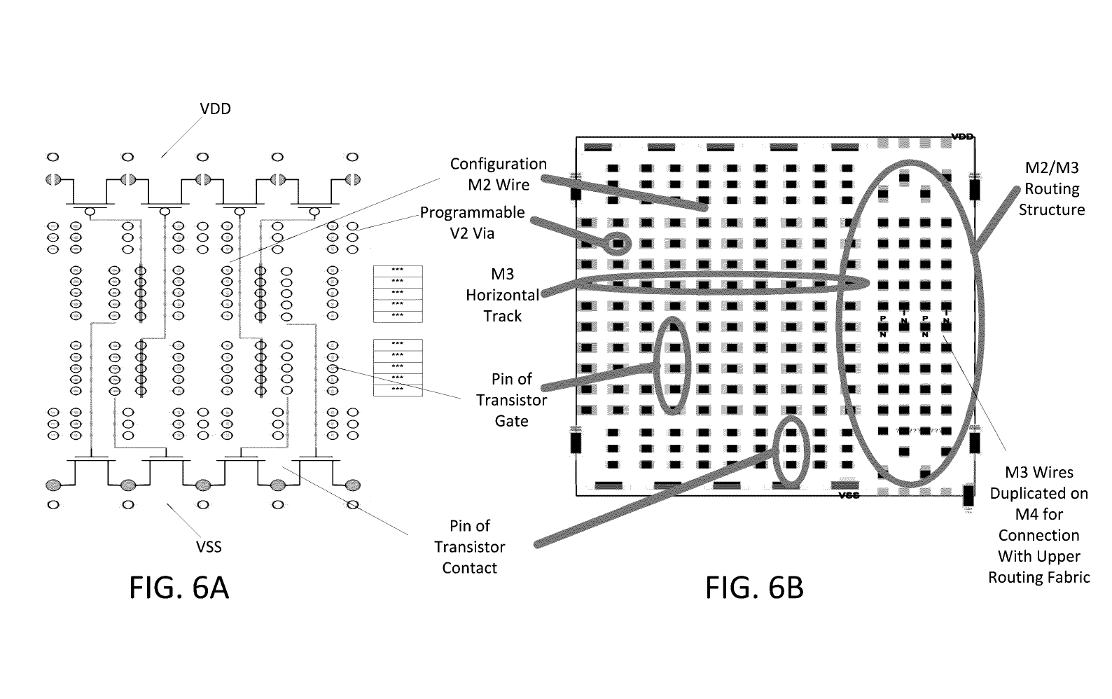

FIGS. 6A and 6B show a schematic and corresponding M2/M3 layout of a logic cell, according to an aspect of this disclosure. This is merely one variant of a logic cell and is merely provided as an illustrative example. Many other variations are possible.

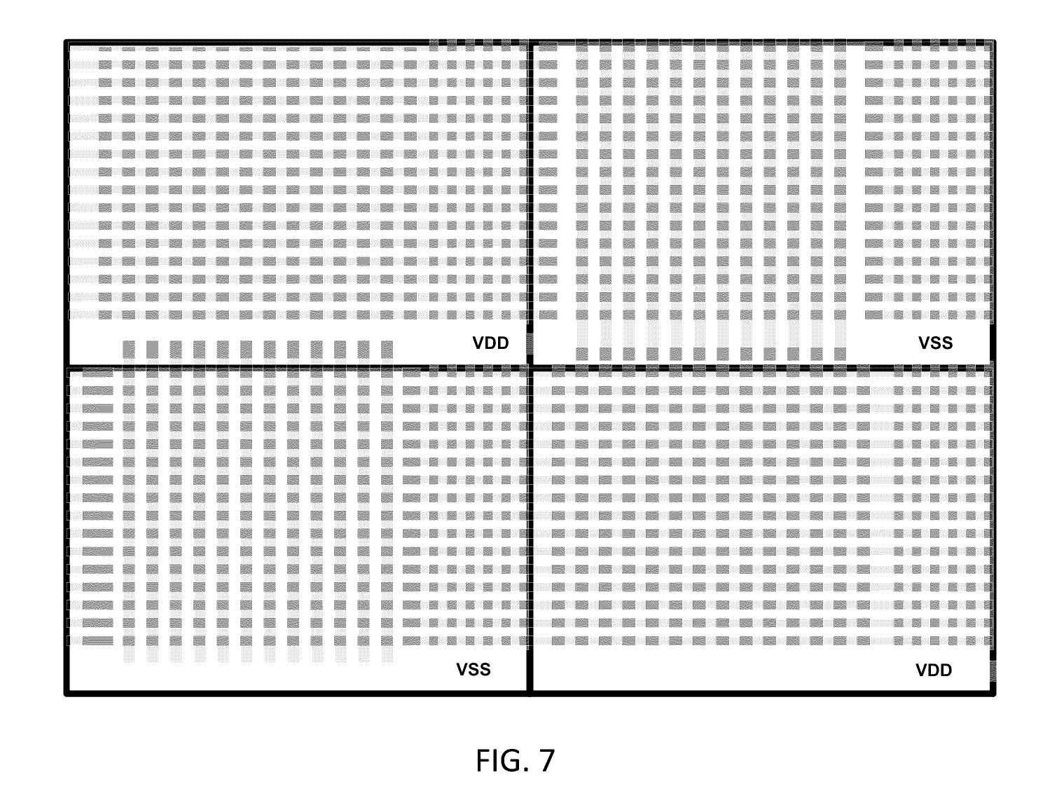

FIG. 7 shows an example of a V4-programmable M4/M5 routing fabric, according to an aspect of this disclosure. In this particular example, the M4/M5 routing fabric is shown for a 2×2 array of logic cells (e.g., eCells™). V4-layer vias may be used to interconnect the wires of M4 and M5 to create customized routing patterns.

As previously noted, the non-limiting examples of FIGS. 3-7 utilize the non-limiting example of FIG. 2, in which V2 and V4 are the only customizable via layers. It is noted that the fabrication of some functional blocks may utilize customization in the V2 layer or the V4 layer or both the V2 and V4 layers. That is, even if multiple customizable via layers are used, some functional blocks may be created using the same subset or different subsets of the customizable via layers; it is also possible that some functional blocks or portions of functional blocks may not require customization of any customizable via layer and may, instead, use a default layout of a respective portion of one or more of the customizable via layers.

It is also stressed that the set of customizable via layers is not limited to V2 and V4, as shown in FIG. 2 and as used in the above examples. In general, any subset of two or more via layers may be customizable, and customization to obtain particular functionality may be obtained through customization of any subset of one or more of the customizable via layers, including a single via layer of the customizable via layers, and as noted above, functional blocks of a single IC may use customization of different layers or different combinations of layers of the subset of customizable via layers.

A structure such as that shown in FIG. 2, having multiple customizable via layers, may be achieved by a number of means. While direct-write e-beam, for example, may be effective for customizing a single customizable via layer, it may be more cost-effective, e.g., for mass production of ICs, to use mask-based techniques. As discussed, for example, in U.S. Pat. No. 6,823,499, incorporated herein by reference, it is possible to create an IC having fixed and custom design parts using mask-based techniques. Custom layers may be sandwiched between fixed, non-customizable layers, and this technique may be used multiple times to create combinations of multiple customizable via layers, e.g., as in FIG. 2. As noted above, such techniques may be used to customize any subset of via layers in a layered structure, such as that shown in FIGS. 1 and 2.

In addition to having customizable via layers, an IC may also be customized using voltage threshold (VT) and/or gate-length variation of the devices in the transistor layers, as shown in FIGS. 1 and 2. VT may affect such factors as speed, power consumption, and/or cost. One may use low-VT (LVT), regular-VT (RVT), or high-VT (HVT) devices, or combinations thereof, in a given design. LVT, RVT and HVT may be relative terms or fixed. However, relative to an RVT device, an LVT device may exhibit higher speed but increased leakage current (and thus greater power consumption), while an HVT device may exhibit lower speed but decreased leakage current. Transistor gate length may similarly affect speed and power within a class of VT devices (LVT, RVT or HVT). VT and/or gate length may be customized by means of VT implant and/or gate fabrication masks used in fabricating the transistor layers.

According to an aspect of this disclosure, VT and gate length variations may be selected based on timing/speed and/or power requirements. Such selection may be performed using a static timing analysis based on the timing and power requirements.

According to another aspect of this disclosure, based on a cost perspective, the variations may be limited to VT variations, in order to reduce costs, in contrast with the customization of gate length.

In a further variation, according to aspects of this disclosure, one or more of the metal layers, e.g., as shown in FIGS. 1 and 2, may also be varied/customized. In one particular case, alluded to above, any subset of the metal layers may be customizable so that particular functionality may be obtained; this may be in combination with customization of a subset of the via layers.

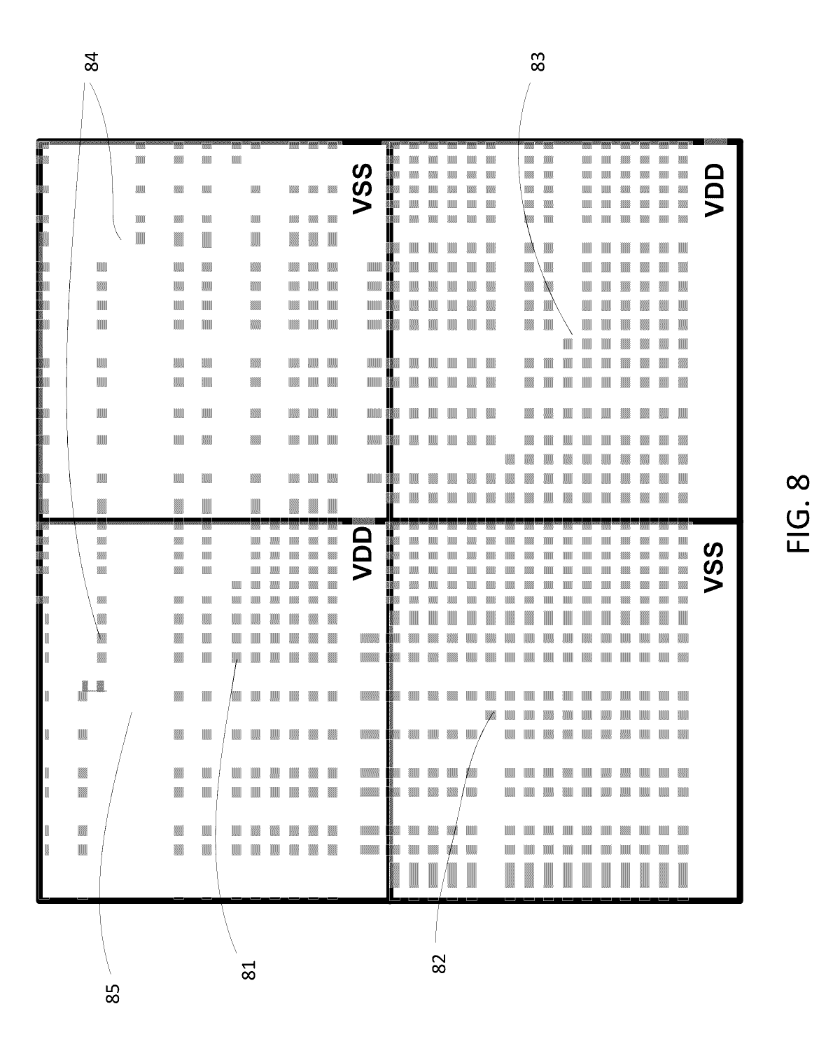

In another particular case, portions of various metal layers may not actually be used in a particular IC design. Nonetheless, such portions may continue to conduct signals, resulting in unnecessary power consumption. Therefore, according to a further aspect of this disclosure, one or more metal layers may be customized, e.g., by removing unused metal, which may then limit interconnect capacity to only that needed for a particular IC design and may result in reduced power consumption. FIG. 8 shows an example of such metal layer customization by removal of unneeded metal. In the example of FIG. 8, metal strips 81, 82, and 83 provide examples in which the lengths of the strips have been shortened, compared with parallel metal strips shown, to eliminate unused portions of metal strips 81, 82 and 83. This may be done by customization of the metal layer prior to fabrication and fabrication of the customized metal layer, or by removal of the unused portions of metal after fabrication of the layer but prior to fabrication of any subsequent (higher) via and/or metal layers. This may be performed on multiple metal layers, if desired, to minimize interconnect capacity to that necessary and reduce dynamic power consumption.

In a further variation, one or more metal layers may be rerouted, which may optimize width and spacing of interconnects, e.g., by redistributing resource(s) of the layer(s) that are not utilized based on the custom design. For example, in FIG. 8, two examples of rerouting, in two metal layers shown in FIG. 8, are indicated by reference numeral 84.

The combination of rerouting and/or elimination of unneeded metal may, in addition to reducing dynamic power consumption, or in conjunction therewith, have additional benefits. For example, removal of metal may permit increased spacing 85 between adjacent metal strips. As a result, capacitance between the adjacent metal strips may be reduced, which may lead to a reduction in cross-talk and/or allow for increased signaling speed. Furthermore, this may enable some increase in widths of one or more metal strips (not shown), which may also reduce resistance in the respective metal strip(s) and may allow for increased signaling speed along the respective metal strip(s).

The above discussion has presented various aspects of this disclosure. It is contemplated that these various aspects may be used in any or all different combinations. For example, all of the different aspects of the disclosure may be used together, in a single device, or any subset of these aspects may be used in a single device. This disclosure is not limited to the use of these different aspects in isolation. For example, a single IC may use a stacked structure, as in FIGS. 1 and 2, which may have two or more customizable via layers and/or at least one customizable metal layer that may be customized for power consumption or speed or functionality and/or customized voltage thresholds and/or gate lengths and/or having a default functionality. The presence or lack of any particular one of these aspects of the disclosure in a given IC is not viewed as essential to the function of the IC.

Various embodiments of the invention have been presented above. However, the invention is not intended to be limited to the specific embodiments presented, which have been presented for purposes of illustration. Rather, the invention extends to functional equivalents as would be within the scope of the appended claims. Those skilled in the art, having the benefit of the teachings of this specification, may make numerous modifications without departing from the scope and spirit of the invention in its various aspects.

What is claimed is:

1. An integrated circuit, including:
transistor layers comprising electronic components or functional blocks or both;
a plurality of alternating metal interconnection layers and via layers, superimposed on the transistor layers, and configured to form interconnections among the electronic components or functional blocks or both, wherein the plurality of alternating metal interconnection layers and via layers includes at least two customizable via layers; and
a contact layer disposed between the plurality of alternating metal interconnection layers and via layers and the transistor layers and configured to provide connectivity between the transistor layers and at least one of the plurality of metal interconnection layers.

2. The integrated circuit of claim 1, wherein the interconnections among the electronic components or functional blocks or both include at least one interconnection that is made by a single one of the at least two customizable via layers.

3. The integrated circuit of claim 1, wherein the interconnections among the electronic components or functional blocks or both include at least one interconnection made using at least two of the at least two customizable via layers.

4. The integrated circuit of claim 1, wherein the plurality of alternating metal interconnection layers and via layers further includes at least one customizable metal interconnection layer.

5. The integrated circuit of claim 1, wherein the metal interconnection layers and via layers include one or more default layers configured to provide a default functionality.

6. The integrated circuit of claim 5, wherein one or more of the one or more default layers is a customizable layer.

7. The integrated circuit of claim 1, wherein the contact layer is customizable.

8. The integrated circuit of claim 1, wherein the electronic components, functional blocks, or both of the transistor layers are interconnected by the contact layer and the plurality of alternating metal interconnection layers and via layers to form one or more further functional blocks.

9. The integrated circuit of claim 8, wherein at least one of the one or more further functional blocks is obtained by customizing a different subset of the at least two customizable via layers from a subset of the at least two customizable via layers customized to obtain another further functional block, wherein the different subset may include zero, one, two, or more of the at least two customizable via layers.

10. The integrated circuit of claim 8, wherein different portions of a single further functional block are obtained by customizing different subsets of the at least two customizable via layers.

11. A method of fabricating an integrated circuit, the method including:
forming transistor layers comprising electronic components or functional blocks or both;
forming a contact layer on the transistor layers;
superimposing on the contact layer a plurality of alternating metal interconnection layers and via layers, wherein the contact layer is configured to provide connectivity between the transistor layers and one or more of the metal layers, wherein the plurality of alternating metal interconnection layers and via layers are configured to provide interconnections among the electronic components or functional blocks or both, wherein the plurality of alternating metal interconnection layers and via layers includes at least two customizable via layers, and wherein the superimposing includes forming the at least two customizable via layers according to respective specified customizations.

12. The method of claim 11, wherein at least one of the metal interconnection layers is customizable, and wherein the superimposing further includes forming the at least one customizable metal interconnection layer according to a specified customization.

13. The method of claim 11, wherein forming the at least two customizable via layers includes using a single one of the at least two customizable via layers to provide at least one customized function to the integrated circuit.

14. The method of claim 11, wherein forming the at least two customizable via layers includes using at least two of the at least two customizable via layers to provide at least one customized function to the integrated circuit.

15. The method of claim 11, wherein the superimposing includes creating a default functionality of the integrated circuit.

16. The method of claim 15, further including receiving from a customer a design specification and using the design specification to modify at least one of the at least two customizable via layers from its default state.

17. The method of claim 11, wherein forming the contact layer includes customizing the contact layer.

18. The method of claim 11, wherein the superimposing comprises using a plurality of masks to form the alternating metal interconnection layers and via layers, and wherein the customizing comprises using at least two customized masks to form the at least two customized via layers.

19. The method of claim 18, wherein the superimposing further comprises using at least one customized mask to form at least one customized metal layer.

20. The method of claim 11, wherein the electronic components or functional blocks or both of the transistor layers are interconnected by the contact layer and the plurality of alternating metal interconnection layers and via layers to form one or more further functional blocks.

21. The method of claim 20, wherein at least one of the one or more further functional blocks is obtained by customizing a different subset of the at least two customizable via layers from a subset of the at least two customizable via layers customized to obtain another further functional block, wherein the different subset comprises zero, one, two, or more of the at least two customizable via layers.

22. The integrated circuit of claim 20, wherein different portions of a single further functional block are obtained by customizing different subsets of the at least two customizable via layers.
